(19) United States
(12) Patent Application Publication
(10) Pub. No.: US 2025/0124346 A1
(43) Pub. Date: Apr. 17, 2025

(54) METHOD AND APPARATUS WITH TRAINING OF SHORT CIRCUIT DETECTION MODEL

(71) Applicants: Samsung Electronics Co., Ltd., Suwon-si (KR); POSTECH RESEARCH AND BUSINESS DEVELOPMENT FOUNDATION, Pohang-si (KR)

(72) Inventors: Myeongjae LEE, Suwon-si (KR); Joonhee KIM, Pohang-si (KR); Soohee HAN, Pohang-si (KR); Jungsoo KIM, Suwon-si (KR); Jinho KIM, Suwon-si (KR); Hangyeol KIM, Pohang-si (KR); Hyosik MOON, Pohang-si (KR); Huiyong CHUN, Suwon-si (KR)

(73) Assignees: Samsung Electronics Co., Ltd., Suwon-si (KR); POSTECH RESEARCH AND BUSINESS DEVELOPMENT FOUNDATION, Pohang-si (KR)

(21) Appl. No.: 18/795,490

(22) Filed: Aug. 6, 2024

(30) Foreign Application Priority Data
Oct. 17, 2023 (KR) 10-2023-0138575

(51) Int. Cl. G06N 20/00; G01R 31/367; G01R 31/389; G01R 31/392

(52) U.S. Cl. CPC G06N 20/00; G01R 31/367; G01R 31/389; G01R 31/392

(57) ABSTRACT

A method and apparatus for training a short circuit detection model are disclosed. The method includes generating virtual battery models with different battery parameter sets, based on battery data measured by a real battery in a non-short circuit state, by applying a constraint corresponding to a short circuit state to the virtual battery models, generating a virtual test result of the short circuit state, and training a short circuit detection model configured to detect the short circuit state using the virtual test result.

### CROSS-REFERENCE TO RELATED APPLICATIONS

This application claims the benefit under 35 USC § 119 (a) of Korean Patent Application No. 10-2023-0138575, filed on Oct. 17, 2023, in the Korean Intellectual Property Office, the entire disclosure of which is incorporated herein by reference for all purposes.

### BACKGROUND

### 1. Field

The following description relates to a method and apparatus with training of a short circuit detection model.

### 2. Description of Related Art

For optimal battery management, the state of a battery may be estimated using various methods. For example, the state of a battery may be estimated by integrating currents of the battery or by using a battery model (for example, an electric circuit model or an electrochemical model). The current integration method involves calculating remaining capacity of a battery by attaching a current sensor to the end of a battery unit (e.g., cell, module, pack, etc.) and adding up the amount of charge being charged and discharged. The electric circuit model method involves using a circuit model that includes a resistor and a capacitor capable of expressing a voltage value that varies as the battery is charged and discharged. The electrochemical model approach models a physical phenomenon inside the battery, such as battery ion concentration and potential.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a method of training a model is performed by a computing device including storage hardware and processing hardware, and the method includes: generating, by the processing hardware, virtual battery models with respective different battery parameter sets, the generating based on battery data measured from a physical reference battery in a non-short circuit state; generating, by the processing hardware, virtual test results of the short circuit state, by applying a constraint corresponding to a short circuit state to the virtual battery models; and training, by the processing hardware, a short circuit detection model configured to detect the short circuit state using the virtual test results, the short circuit detection model configured to receive a measurement of a battery as an input and infer therefrom a short circuit state of the battery.

The generating of the virtual battery models may include, based on indications of performance of respective candidate virtual battery models generated by an optimization process for a battery parameter, selecting the virtual battery models from among the candidate virtual battery models.

The constraint may be set by assigning a resistance value of a predetermined level to a battery separator component of the virtual battery models.

The short circuit state may be associated with different resistance levels, and virtual test results corresponding to a number of the virtual battery models multiplied by a number of resistance levels of the non-short circuit state and by the different resistance levels of the short circuit state may be generated as the constraint is applied to the virtual battery models.

There may be over one hundred virtual battery models and the different resistance levels may be two or more resistance levels.

The short circuit detection model may include: a neural network included of layers of respective nodes, the nodes of adjacent layers having weights of connections therebetween, the layers may include: compression layers configured to generate feature data by compressing input battery data; and detection layers configured to perform short circuit detection based on the feature data.

The compression layers may include: a first layer configured to process a specific type of the input battery data; a second layer configured to perform primary compression by performing a first pooling operation on an output of the first layer; a third layer configured to apply a batch normalization (BN) and a nonlinear function to an output of the second layer; and a fourth layer configured to perform secondary compression by performing a second pooling operation on an output of the third layer.

The detection layers may include a fully connected (FC) layer configured to classify the feature data into one of different resistance levels of the non-short circuit state and the short circuit state and output indications of the classifications.

The virtual test result may correspond to a partial charging section of a charging profile, and the measurement of the battery may correspond to the partial charging section.

The partial charging section may correspond to constant voltage (CV) and rest sections.

The virtual battery models may model electrochemical thermal (ECT) properties of batteries.

The short circuit detection model may be a neural network model.

The method may further include determining the virtual test results by applying an optimization process thereto.

In another general aspect, an apparatus for training a model includes: one or more processors; and a memory storing instructions configured to cause the one or more processors to: generate virtual battery models with respective different battery parameter sets, based on battery data measured from a physical reference battery that is in a non-short circuit state; by applying a constraint corresponding to a short circuit state to the virtual battery models, generate a virtual test result of the short circuit state; and train a short circuit detection model configured to detect the short circuit state using the virtual test result, the short circuit detection model configured to receive a measurement of a battery as an input and infer therefrom a short circuit state of the battery.

The instructions may be further configured to cause the one or more processors to, based on indications of performance of respective candidate virtual battery models generated by an optimization process for a battery parameter, select the virtual battery models from among the candidate virtual battery models.

The constraint may be set by assigning a resistance value of a predetermined level to a battery separator component of the virtual battery models.

The short circuit state may include different resistance levels, wherein virtual test results corresponding to a number of the virtual battery models multiplied by a number of a resistance level of the non-short circuit state and by the different resistance levels of the short circuit state are generated as the constraint is applied to the virtual battery models.

The short circuit detection model may include: a neural network included of layers of respective nodes, the nodes of adjacent layers having weights of connections therebetween, the layers including: compression layers configured to generate feature data by compressing input battery data; and detection layers configured to perform short circuit detection based on the feature data.

The compression layers may include: a first layer configured to process a specific type of the input battery data; a second layer configured to perform primary compression by performing a first pooling operation on an output of the first layer; a third layer configured to apply a batch normalization (BN) and a nonlinear function to an output of the second layer; and a fourth layer configured to perform secondary compression by performing a second pooling operation on an output of the third layer.

The detection layer group may include a fully connected (FC) layer configured to classify the feature data into one of different resistance levels of the non-short circuit state and the short circuit state and output indications of the classifications.

Other features and aspects will be apparent from the following detailed description, the drawings, and the claims.

### BRIEF DESCRIPTION OF THE DRAWINGS

FIG. 1 illustrates an example of training a short circuit detection model, according to one or more embodiments.

FIG. 2 illustrates an example of deriving battery parameter sets, according to one or more embodiments.

FIG. 3 illustrates an example of deriving large-scale virtual test results, according to one or more embodiments.

FIG. 4 illustrates an example of a short circuit detection model, according to one or more embodiments.

FIG. 5 illustrates an example of a training process, according to one or more embodiments.

FIG. 6 illustrates an example configuration of a model training apparatus, according to one or more embodiments.

FIG. 7 illustrates an example of detecting a short circuit, according to one or more embodiments.

FIG. 8 illustrates an example of an electronic device, according to one or more embodiments.

FIG. 9 illustrates an example method of training a model, according to one or more embodiments.

Throughout the drawings and the detailed description, unless otherwise described or provided, the same or like drawing reference numerals will be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

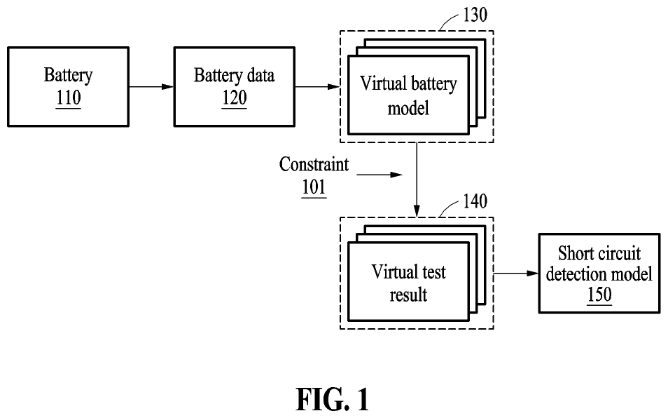

FIG. 1 illustrates an example of training a short circuit detection model, according to one or more embodiments. Referring to FIG. 1, battery data 120 may be measured by a battery 110. The battery 110 may be a real/physical battery, also referred to as a reference battery. For example, the battery 110 may be a beginning-of-life (BOL) battery that is used for the first time without prior data, and a short circuit detection model 150 may be trained to detect a short circuit of the battery 110. That is, the battery 110 may be in a “pristine” or factory-finished state. The term “short circuit” as used herein refers to an internal short circuit of the battery 110.

The battery data 120 may include data associated with the specification and/or operation of the battery 110. For example, when the battery 110 is being charged, the battery data 120 may include a signal of the battery 110 according to charging, and when the battery 110 is being discharged, the battery data 120 may include a signal of the battery 110 according to discharging. For example, the battery signal may include voltage, current, and/or temperature, etc. of the battery 110. The battery data 120 may be measured by various sensor(s) inside and/or outside the battery 110. Some aspects of the battery data 120 may be obtained by analog to digital conversion of sensor signals. The battery data 120 may include a time dimension, e.g., data samples in the battery data 120 may have respective times at which they were captured.

The battery data 120 may be measured by the battery 110 in a non-short circuit state. The non-short circuit state may be a normal state. Virtual battery models 130 may be generated based on the battery data 120. Each of the virtual battery models 130 may correspond to a distinct battery parameter set (e.g., in a one-to-one correspondence). The virtual battery models 130 may have different battery parameter sets.

The virtual battery models 130 may be electrochemical thermal (ECT) models. An ECT model may replicate/approximate an internal state of the battery 110 using various battery parameters and a governing equation. The battery parameter may also be referred to as an ECT parameter. For example, the battery parameters of an ECT model may indicate a shape (for example, thickness, and/or radius, etc.), an open circuit potential (OCP), and physical properties (for example, electrical conductivity, ionic conductivity, and/or diffusion coefficient). The governing equations may include equations modeling an electrochemical reaction occurring at an interface between an electrode and an electrolyte based on these battery parameters, and a physical conservation equation associated with the electrode and with a conservation of a concentration of the electrolyte and electrical charges. An ECT model may estimate a state (e.g., a state of charge (SOC), voltage, etc.) of the battery 110 based on the battery data 120. For example, an ECT model may estimate the voltage and/or SOC of the battery 110 based on the current and/or temperature of the battery 110 according to the battery data 120. For example, the battery data 120 may provide one or more battery parameter values to an ECT model, which, based on the battery parameter values, may output state of the battery 110.

An optimization process may be executed (by processing hardware) to optimize the virtual battery models' 130 replication (approximation) of the battery 110. In the optimization process, values of the battery parameters of the virtual battery models 130 may be adjusted such that the virtual battery models 130 represent data close to the battery data 120 of the battery 110 (i.e., so that the battery models 130 closely model the battery 110 according to the battery data 120). The optimization process may generate various candidate virtual battery models for the battery parameters. For example, candidate virtual battery models with varying performances may be generated during the optimization process. Here, “performance” refers to how well the virtual battery models 130 model the battery 110, i.e., similarity of the virtual battery models 130 to the battery 110. For example, a virtual battery model that estimates (outputs) data that is most similar to the battery data 120 of the battery 110 may be evaluated as having the highest performance (e.g., among various candidate virtual battery models). For example, an average voltage error may be used for performance evaluation. The virtual battery models 130 may be selected from the candidate virtual battery models based on the performances of the respective candidate virtual battery models. For example, a predetermined number of the virtual battery models 130 may be selected from the candidate virtual battery models in order of high performance (e.g., the top-N models may be selected). As another example, the candidate virtual battery models with an average voltage error of 1% or 2% may be selected as the virtual battery models 130.

A constraint 101 may be applied to each of the virtual battery models 130, and thus-constrained virtual test results 140 may be generated accordingly. The constraint 101 may be a resistance value assigned, at a predetermined level, to a battery separator component of the virtual battery models 130. For example, low-level resistance values such as 50 ohms (Ω), 1000, 200Ω, and 500Ω may cause, in a modeling sense, a current to flow through the battery separator component, thereby simulating inducement of a short circuit phenomenon in which the anode and cathode of the virtual battery models 130 conductively contact with each other. A high-level resistance value, such as 10,000Ω, may, in a modeling sense, conductively separate the anode and cathode such that the virtual battery models 130 are in the non-short circuit state. These resistance values are only examples and are non-limiting. When a resistance level that induces the short circuit state is used as the constraint 101, a virtual test result of the short circuit state may be generated. Similarly, when a resistance level that results in the non-short circuit state is used as the constraint 101, a virtual test result of the non-short circuit state may be generated. In sum, by varying the resistance level constraint, short and non-short states may be generated by the virtual battery models 130.

The short circuit state may correspond to different resistance levels such as, but not limited to, 50Ω, 100Ω, 200Ω, and 500Ω, as examples. As the constraint 101 is applied to the virtual battery models 130 in large scale, the corresponding virtual test results may be generated in a quantity corresponding to a product of (i) the number of virtual battery models 130 and (ii) the number of resistance levels of the non-short circuit state and the short circuit state. For example, if there are 100 virtual battery models 130 there are two resistance levels, then there may be 200 virtual test results. For example, if the number of virtual battery models 130 is 500 and the number of resistance levels is 5, then 2,500 virtual test results 140 may be derived. These quantities are only examples.

The short circuit detection model 150 may be trained to detect the short circuit state, based on input battery data (battery data inputted to the short circuit detection model 150). The short circuit detection model 150 may be a neural network model. The neural network may include a deep neural network (DNN) including multiple layers (e.g., an input layer, hidden layers, and an output layer). The DNN may include at least one of a fully connected network (FCN), a convolutional neural network (CNN), or a recurrent neural network (RNN). For example, at least some of the layers included in the neural network may correspond to the CNN, and others may correspond to the FCN. The CNN may be referred to as a convolutional layer, and the FCN may be referred to as a fully connected (FC) layer.

The neural network may be trained based on deep learning and may perform inference suitable for a purpose of the training by mapping input data and output data that are in a nonlinear relationship to each other. Deep learning may be a machine learning technique for solving an issue, such as image or speech recognition, from a large data set. Deep learning may be construed as an optimization problem-solving process of finding a point at which energy is minimized while training a neural network using prepared training data. Through supervised or unsupervised learning of deep learning, a structure of the neural network and/or a weight corresponding to a model may be obtained, and the input data and the output data may be mapped to each other through the weight. When the width and the depth of the neural network are sufficient, the neural network may have a capacity sufficient to implement a predetermined function. The neural network may achieve an optimized performance by learning a sufficiently large amount of training data through an appropriate training process.

The short circuit detection model 150 may be trained based on the virtual test results 140. The virtual test results 140 may have a sufficient quantity of samples (test results) to train the short circuit detection model 150. In addition the virtual test results 140 may be enlarged by using data augmentation techniques on the virtual test results 140 and/or by increasing number of constraints 101 of the virtual battery models 130.

The short circuit detection model 150 may include a compression layer group (e.g., one or more layers) that generates feature data by compressing input battery data and a detection layer group (e.g., one or more layers) that performs short circuit detection based on the feature data. The compression layer group may include a first layer that processes a type of the input battery data, a second layer that performs primary compression by performing a first pooling operation on an output of the first layer, a third layer that applies a batch normalization (BN) and a nonlinear function to an output of the second layer, and a fourth layer that performs secondary compression by performing a second pooling operation on an output of the third layer. The detection layer group may include an FC layer that classifies the feature data into one of different resistance levels of the non-short circuit state and short circuit state (each state may have one or more resistance levels). As noted above, a layer may be a set of nodes with weighted connections to an adjacent layer.

When the virtual battery models 130 are employed for performing the parameter optimization for each temperature and state of health (SOH), a virtual test result of the short circuit state may be obtained for each temperature and SOH, for each virtual battery model, and the short circuit detection model 150 may be trained using the virtual test results. In this case, in addition to the battery 110 in the BOL state, short circuit detection that secures robustness may be extended to various battery aging states and temperatures.

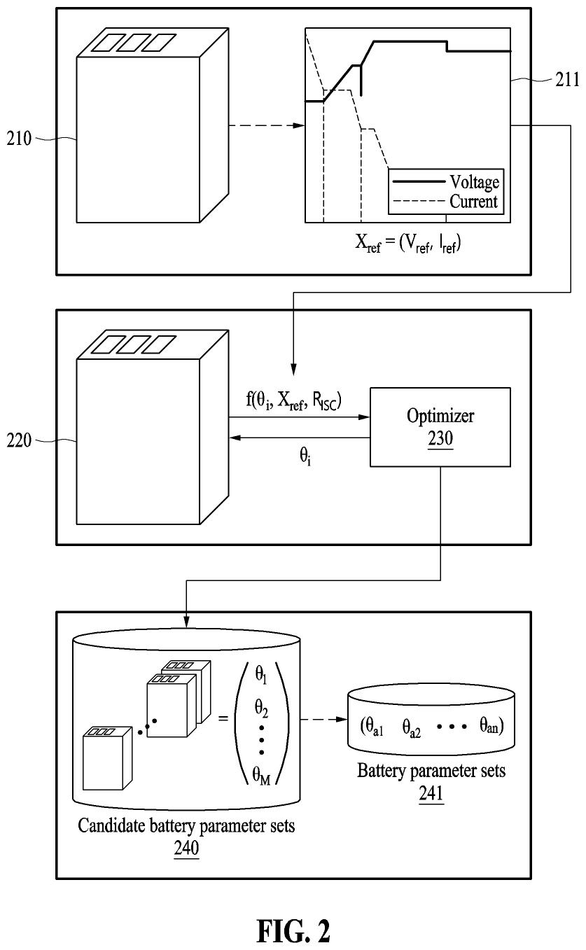

FIG. 2 illustrates an example of deriving battery parameter sets, according to one or more embodiments. Referring to FIG. 2, battery data sample 211 may be measured by a battery 210. For example, the battery data sample 211 may include voltage data and current data. The battery data sample 211 may be represented as X_{ref}, the voltage data may be represented as V_{ref}, and the current data may be represented as I_{ref}. These values may vary with time (represented by the horizontal axis of the example battery data sample 211 shown in FIG. 2).

An optimizer 230 may optimize a battery parameter of a virtual battery model 220. The battery parameter in this example is represented as θ, a separator resistance is represented as R_{ISC}, and an objective function for optimization is represented as f. The optimization may be performed repeatedly, with i representing an iteration index. For example, candidate battery parameter sets 240 of θ₁ to θ_{M} may each be generated through respective iterative optimization processes. The candidate battery parameter sets 240 may correspond to candidate virtual battery models, respectively. Battery parameter sets 241 may be selected from the candidate battery parameter sets 240. For example, n battery parameter sets 241 may be selected from the candidate battery parameter sets 240 in order of performance. The n battery parameter sets 241 are represented as θₐ₁ to θₐₙ.

The optimization may be performed with metaheuristic-based optimization, for example. With a metaheuristic optimization algorithm, an optimal solution may be found through random sampling (possibly in combination with some other techniques) rather than a gradient descent method (which finds an optimal solution through a gradient of a loss function). In this case, since many samples such as the candidate battery parameter sets 240 are detected that are somewhat near the optimal solution, parameters that are somewhat good (in terms of replicating a response of the battery 210) may be obtained (in addition to, possibly, an optimal parameter). Among the candidate battery parameter sets 240, some with certain sufficient performance may be selected as the battery parameter sets 241 (e.g., top-N, top X %, above a threshold, etc.).

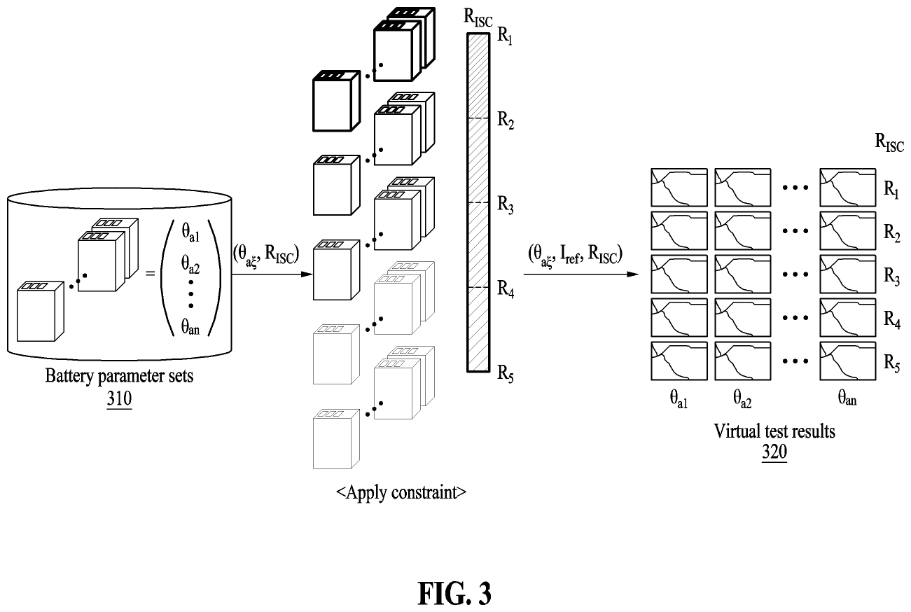

FIG. 3 illustrates an example of deriving large-scale virtual test results, according to one or more embodiments. Referring to FIG. 3, a constraint may be applied to battery parameter sets 310. The constraint is represented as R_{ISC}, which is the resistance level of a separator. For example, R_{ISC} may include resistance values of R₁ to R₅. For example, R₁ may be 50Ω (i.e., R₁=50Ω), R₂ may be 100Ω (i.e., R₂=100Ω), R₃ may be 200Ω (i.e., R₃=200Ω), R₄ may be 500Ω (i.e., R₄=500Ω), and R₅ may be 10,000Ω (i.e., R₅=10,000Ω) but are not limited thereto. R₁ to R₄ may correspond to the short circuit state and R₅ may correspond to the non-short circuit state. The battery parameter sets 310 are represented as θₐ₁ to θₐₙ. When the constraint of R₁ to R₅ is applied to θₐ₁ to θₐₙ, n×5 virtual test results 320 may be generated (for 5 resistance values). For example, when n is 500, 2,500 virtual test results 320 in large-scale may be generated. As noted above, the numerical values discussed herein are non-limiting examples.

The virtual test results 320 may include respectively corresponding battery data items. A battery data item may include voltage data and current data, in which case the virtual test results 320 may also each include respective voltage data and current data. For example, current data I_{ref} of the battery data items may be input to each of virtual battery models corresponding to the battery parameter sets 310, and accordingly, a voltage response of each of the virtual battery models may be recorded as corresponding voltage data.

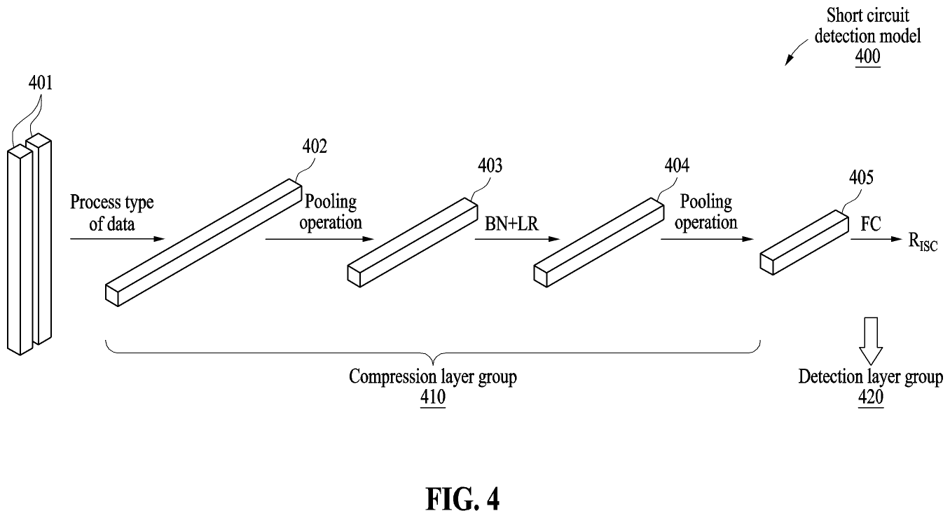

FIG. 4 illustrates an example structure of a short circuit detection model, according to one or more embodiments. Referring to FIG. 4, a short circuit detection model 400 may include a compression layer group 410 and a detection layer group 420. The short circuit detection model 400 may be capable of short circuit detection with low computing power by processing lightweight data through a lightweight structure.

The compression layer group 410 and the detection layer group 420 may each include at least one layer. For example, the compression layer group 410 may include a first layer that generates first intermediate data 402 by processing a type of data of input battery data 401 (e.g., a voltage dimension and a current dimension), a second layer that generates second intermediate data 403 by performing a pooling operation on the first intermediate data 402, a third layer that generates third intermediate data 404 by applying a BN and a nonlinear function to the second intermediate data 403, and a fourth layer that generates fourth intermediate data 405 by performing a pooling operation on the third intermediate data 404. The fourth intermediate data 405 may correspond to feature data of the input battery data 401.

For example, the nonlinear function may be a leakyReLU (LR). The FC layer may classify the fourth intermediate data 405 into one of different resistance levels of the non-short circuit state and the short circuit state. For example, R_{ISC} may include resistance levels of R₁ to R₅ and the FC layer may select one of the resistance levels of R₁ to R₅ corresponding to the fourth intermediate data 405. When one of the resistance levels of R₁ to R₅ corresponding to the short circuit state is selected, the short circuit state is detected.

For example, the input battery data 401 may have a dimension of 2×6500. For example, the input battery data 401 may include time-series current data with a dimension of 6500 (6500 current samples) and time-series voltage data with a dimension of 6500. Flattening may be performed for processing each type of input data. The input battery data 401 may be transformed into the first intermediate data 402 with a dimension of 13000. The second intermediate data 403 may be generated by performing an average pooling operation on the first intermediate data 402. For example, 10 elements may be averaged in the first intermediate data 402, which case, in the example of the first intermediate data 402 (having a dimension of 13000, the second intermediate data 403 will have a dimension of 130.

The third intermediate data 404 may be generated as the BN and the nonlinear function are applied to the second intermediate data 403. In this example, the third intermediate data 404 may have a dimension of 130. The third intermediate data 404 may be generated using a max pooling operation on the third intermediate data 404. For example, the pooling may be performed for every 10 elements, and the fourth intermediate data 405 with a dimension of 13 may be generated. As thus described, feature data such as the fourth intermediate data 405 may be generated through compression of the input battery data 401 by the compression layer group 410. As noted, the numerical dimension values described above are non-limiting examples.

In the short circuit detection model 400, the BN layer and the FC layer may have adjustable parameters. During a training process, virtual test results may be used as the input battery data 401, and resistance values of the constraint used to generate the virtual test results may be used as ground truth (GT). As the parameters (e.g., weights) of the BN layer and the FC layer are adjusted during the training process, the short circuit detection model 400 may gat ability to detect short circuits from the input battery data 401.

The short circuit detection model 400 may be trained based on Equation 1 below.

$$Loss = {\sum }_{i = 1}^{q} P ( {R}_{{ISC}_{i}} ) \cdot log P ( {\hat{R}}_{{ISC}_{i}} ) + {\sum }_{j = 1}^{q} {α}_{i} \cdot P ( {R}_{{ISC}_{j}} ) \cdot log P ( {\hat{R}}_{{ISC}_{j}} ) + {\sum }_{k} ( β \cdot \vert {W}_{k} \vert + γ \cdot {W}_{k}^{2} ) \qquad Equation 1$$

In Equation 1, “Loss” denotes a loss value and α, β, and γ denote a weight for each resistance for a sample that failed classification, a weight for an L1 regularization, and a weight for an L2 regularization, respectively. i, j, k, q, and W respectively denote an index for resistance, an index for a sample for each resistance that failed classification, an index for a learning parameter (e.g., a weight) of the short circuit detection model 400, the total number of resistance levels of the non-short circuit state and the short circuit state, and a learning parameter of the short circuit detection model 400, respectively.

For a given charging profile to be subjected to short detection, the short circuit detection model 400 may have the ability to detect a short circuit for a section of the charging profile to which the battery data and virtual test results belong. For example, when the battery data and virtual test results are obtained from the entire section in the charging profile, the short circuit detection model 400 may perform short circuit detection on the input battery data 401 corresponding to the entire charging profile. When the battery data and virtual test results are obtained from a partial section in the charging profile, the short circuit detection model 400 may perform short circuit detection on the input battery data 401 corresponding to the partial section. The partial section may be defined based on multi-level charging. For example, there may be a constant voltage (CV) charging section and a rest section of constant current-constant voltage (CC-CV) charging. Since the CV section and rest section are most frequently used, the probability of short circuit detection may increase due to the use of the CV section and rest section.

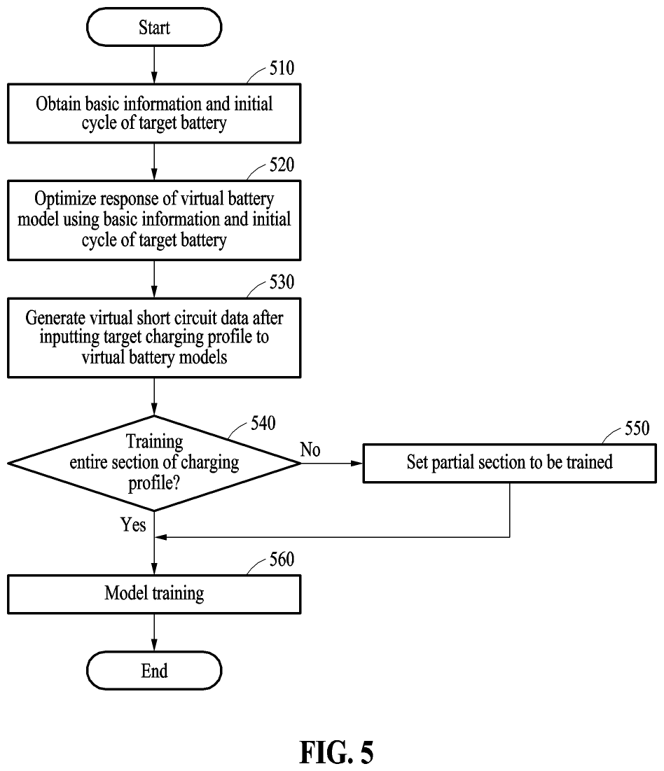

FIG. 5 illustrates an example training process, according to one or more embodiments. Referring to FIG. 5, in operation 510, basic information and an initial cycle of a target battery may be obtained. The target battery may be a BOL battery. Battery data may be configured based on the basic information and the initial cycle. In operation 520, a response of a virtual battery model may be optimized using the basic information and the initial cycle of the target battery. For example, metaheuristic-based voltage response optimization may be performed. Virtual battery models may be derived during the optimization process.

In operation 530, virtual short circuit data may be generated after inputting a target charging profile to the virtual battery models. The virtual short circuit data may correspond to virtual test results. In operation 540, it is determined whether to train the entire section of the charging profile. When training of a partial section is required, the partial section to be trained may be set in operation 550. In operation 560, model training in the entire section or the partial section may be performed. A short circuit detection model may have an ability to detect the short circuit in the entire section or the partial section of the charging profile according to the model training.

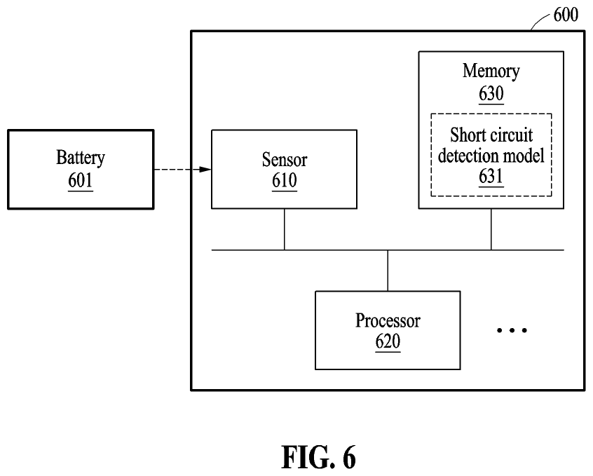

In addition, the descriptions provided with reference to FIGS. 1 to 4 and the descriptions provided with reference to FIGS. 6 to 9 may generally apply to the training operation of FIG. 5.

FIG. 6 illustrates an example configuration of a model training apparatus, according to one or more embodiments. Referring to FIG. 6, a model training apparatus 600 may include a sensor 610, a processor 620, and a memory 630. Although not shown in FIG. 6, the model training apparatus 600 may further include other devices such as a storage device, an input device, an output device, and a network device.

The memory 630 may be connected to the processor 620 and may store instructions executable by the processor 620, data to be operated by the processor 620, or data processed by the processor 620. The memory 630 may include, for example, a non-transitory computer-readable storage medium, for example, high-speed random access memory (RAM) and/or a non-volatile computer-readable storage medium (for example, a disk storage device, a flash memory device, or other non-volatile solid state memory devices).

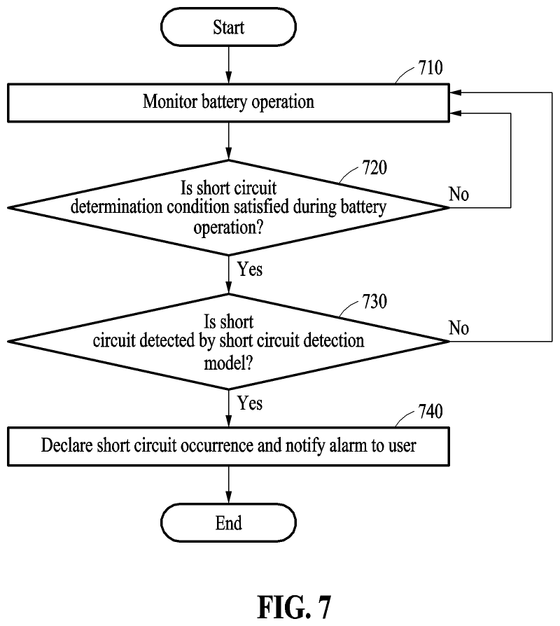

The processor 620 may execute instructions to perform the operations of FIGS. 1 to 5 and the operations of FIGS. 7 to 9. The processor 620 may be one processor or a combination of processors. For example, the processor 620 may generate virtual battery models with different battery parameter sets, based on battery data measured by a battery 601 in a non-short circuit state, by applying a constraint corresponding to a short circuit state to the virtual battery models. The processor 620 may also generate a virtual test result of the short circuit state, and train a short circuit detection model 631 that detects the short circuit state using the virtual test result. The battery data of the battery 601 may be measured through the sensor 610. The sensor 610 may include various sensors inside and/or outside the battery 601.

In addition, the descriptions provided with reference to FIGS. 1 to 5 and the descriptions provided with reference to FIGS. 7 to 9 may generally apply to the model training apparatus 600.

FIG. 7 illustrates an example of detecting a short circuit, according to one or more embodiments. Referring to FIG. 7, in operation 710, a battery operation may be monitored. In operation 720, it may be checked whether a short circuit determination condition is satisfied during the battery operation. For example, the short circuit determination condition may include determining whether a monitored section corresponds to a pre-trained section (e.g., the entire charging section or partial charging section) for the short circuit detection by a short circuit detection model. The model may be a neural network model trained as described above. Operation 730 may be performed when the short circuit determination condition is satisfied. In operation 730, it may be checked whether the short circuit is detected by the short circuit detection model. The short circuit detection model may perform short circuit detection based on input battery data. When the short circuit is detected, operation 740 may be performed. In operation 740, a short circuit occurrence may be declared and an alarm may be notified to a user. When the short circuit determination condition is not satisfied or the short circuit detection is not performed, operation 710 may be performed repeatedly.

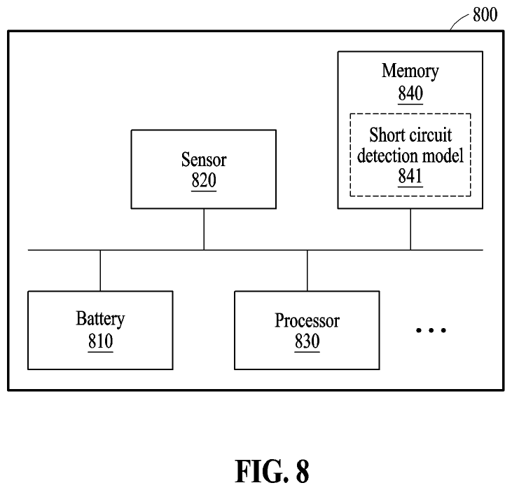

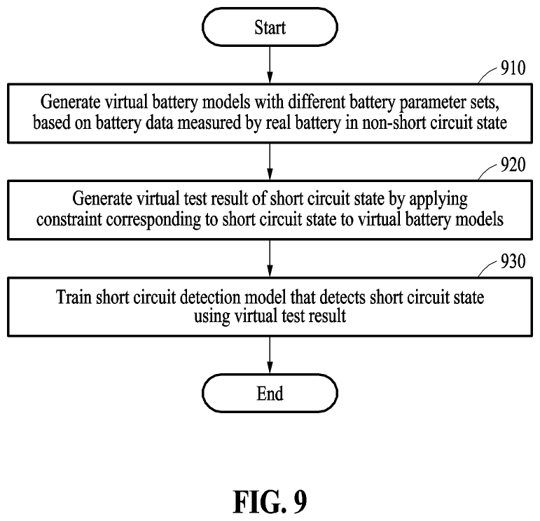

In addition, the descriptions provided with reference to FIGS. 1 to 6 and the descriptions provided with reference to FIGS. 8 and 9 may generally apply to the short circuit detection operation of FIG. 7.

FIG. 8 illustrates an example configuration of an electronic device, according to one or more embodiments. Referring to FIG. 8, an electronic device 800 may include a battery 810, a sensor 820, a processor 830, and a memory 840. Although not shown in FIG. 8, the electronic device 800 may further include other devices such as a storage device, an input device, an output device, and a network device. For example, the electronic device 800 may be implemented on mobile devices such as mobile phones, smartphones, personal digital assistants (PDAs), netbooks, tablet computers, laptop computers, etc., wearable devices such as smart watches, smart bands, smart glasses, etc., and vehicles such as autonomous vehicles, smart vehicles, etc.

The memory 840 may be connected to the processor 830 and may store instructions executable by the processor 830, data to be operated by the processor 830, or data processed by the processor 830. The memory 840 may include, for example, a non-transitory computer-readable storage medium, for example, RAM and/or a non-volatile computer-readable storage medium (for example, a disk storage device, a flash memory device, or other non-volatile solid state memory devices).

The processor 830 may execute instructions to perform the operations of FIGS. 1 to 7 and the operations of FIG. 9. For example, the processor 830 may execute a short circuit detection model 841 to detect a short circuit of the battery 810 based on input battery data of the battery 810. The input battery data of the battery 810 may be measured through the sensor 820. The sensor 820 may include various sensors inside and/or outside the battery 810.

In addition, the descriptions provided with reference to FIGS. 1 to 7 and the descriptions provided with reference to FIG. 9 may also apply to the electronic device 800.

FIG. 9 illustrates an example of training a model, according to one or more embodiments. Referring to FIG. 9, a model training apparatus may generate virtual battery models with different battery parameter sets, based on battery data measured by a real battery in a non-short circuit state in operation 910, by applying a constraint corresponding to a short circuit state to the virtual battery models, generate a virtual test result of the short circuit state in operation 920, and train a short circuit detection model that detects the short circuit state using the virtual test result in operation 930.

Operation 910 may include, based on the performance of candidate virtual battery models generated by an optimization process for a battery parameter, selecting the virtual battery models from the candidate virtual battery models.

The constraint may assign a resistance value at a predetermined level to a battery separator of the virtual battery models.

The short circuit state may include different resistance levels, and large-scale virtual test results corresponding to a product of the number of the virtual battery models and the number of resistance levels of the non-short circuit state and the different resistance levels of the short circuit state may be generated as the constraint is applied to the virtual battery models.

The virtual battery models may be 100 or more and the resistance levels may be two or more.

The short circuit detection model may include a compression layer group that generates feature data by compressing the input battery data and a detection layer group that performs short circuit detection based on the feature data.

The compression layer group may include a first layer that processes a type of input battery data, a second layer that performs primary compression by performing a first pooling operation on an output of the first layer, a third layer that applies a BN and a nonlinear function to an output of the second layer, and a fourth layer that performs secondary compression by performing a second pooling operation on an output of the third layer.

The detection layer group may include an FC layer that classifies the feature data into one of different resistance levels of the non-short circuit state and the short circuit state.

The virtual test result may relate to a partial charging section, and the short circuit detection model may detect the short circuit state based on the input battery data in the partial charging section.

The partial charging section may correspond to CV and rest sections.

The virtual battery models may be ECT models.

The short circuit detection model may be a neural network model.

In addition, the descriptions provided with reference to FIGS. 1 to 8 may generally apply to the training method of FIG. 9.

The computing apparatuses, the electronic devices, the processors, the memories, the models, the displays, the information output system and hardware, the storage devices, and other apparatuses, devices, units, modules, and components described herein with respect to FIGS. 1-9 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-9 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RW, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. A method of training a model, the method performed by a computing device comprising storage hardware and processing hardware, the method comprising:
generating, by the processing hardware, virtual battery models with respective different battery parameter sets, the generating based on battery data measured from a physical reference battery in a non-short circuit state;
generating, by the processing hardware, virtual test results of the short circuit state, by applying a constraint corresponding to a short circuit state to the virtual battery models; and
training, by the processing hardware, a short circuit detection model configured to detect the short circuit state using the virtual test results, the short circuit detection model configured to receive a measurement of a battery as an input and infer therefrom a short circuit state of the battery.

2. The method of claim 1, wherein the generating of the virtual battery models comprises, based on indications of performance of respective candidate virtual battery models generated by an optimization process for a battery parameter, selecting the virtual battery models from among the candidate virtual battery models.

3. The method of claim 1, wherein the constraint is set by assigning a resistance value of a predetermined level to a battery separator component of the virtual battery models.

4. The method of claim 1, wherein the short circuit state is associated with different resistance levels,
wherein virtual test results corresponding to a number of the virtual battery models multiplied by a number of resistance levels of the non-short circuit state and by the different resistance levels of the short circuit state are generated as the constraint is applied to the virtual battery models.

5. The method of claim 4, wherein
there are over one hundred virtual battery models, and
the different resistance levels are two or more resistance levels.

6. The method of claim 1, wherein the short circuit detection model comprises:
a neural network comprised of layers of respective nodes, the nodes of adjacent layers having weights of connections therebetween, the layers including:
compression layers configured to generate feature data by compressing input battery data; and
detection layers configured to perform short circuit detection based on the feature data.

7. The method of claim 6, wherein the compression layers comprise:
a first layer configured to process a specific type of the input battery data;
a second layer configured to perform primary compression by performing a first pooling operation on an output of the first layer;
a third layer configured to apply a batch normalization (BN) and a nonlinear function to an output of the second layer; and
a fourth layer configured to perform secondary compression by performing a second pooling operation on an output of the third layer.

8. The method of claim 6, wherein the detection layers comprise a fully connected (FC) layer configured to classify the feature data into one of different resistance levels of the non-short circuit state and the short circuit state and output indications of the classifications.

9. The method of claim 1, wherein
the virtual test result corresponds to a partial charging section of a charging profile, and
the measurement of the battery corresponds to the partial charging section.

10. The method of claim 9, wherein the partial charging section corresponds to constant voltage (CV) and rest sections.

11. The method of claim 1, wherein the virtual battery models model electrochemical thermal (ECT) properties of batteries.

12. The method of claim 1, wherein the short circuit detection model is a neural network model.

13. The method of claim 1, further comprising determining the virtual test results by applying an optimization process thereto.

14. An apparatus for training a model, the apparatus comprising:
one or more processors; and
a memory storing instructions configured to cause the one or more processors to:
generate virtual battery models with respective different battery parameter sets, based on battery data measured from a physical reference battery that is in a non-short circuit state;
by applying a constraint corresponding to a short circuit state to the virtual battery models, generate a virtual test result of the short circuit state; and
train a short circuit detection model configured to detect the short circuit state using the virtual test result, the short circuit detection model configured to receive a measurement of a battery as an input and infer therefrom a short circuit state of the battery.

15. The apparatus of claim 14, wherein the instructions are further configured to cause the one or more processors to, based on indications of performance of respective candidate virtual battery models generated by an optimization process for a battery parameter, select the virtual battery models from among the candidate virtual battery models.

16. The apparatus of claim 14, wherein the constraint is set by assigning a resistance value of a predetermined level to a battery separator component of the virtual battery models.

17. The apparatus of claim 14, wherein the short circuit state comprises different resistance levels,
wherein virtual test results corresponding to a number of the virtual battery models multiplied by a number of a resistance level of the non-short circuit state and by the different resistance levels of the short circuit state are generated as the constraint is applied to the virtual battery models.

18. The apparatus of claim 14, wherein the short circuit detection model comprises:
a neural network comprised of layers of respective nodes, the nodes of adjacent layers having weights of connections therebetween, the layers including:
compression layers configured to generate feature data by compressing input battery data; and
detection layers configured to perform short circuit detection based on the feature data.

19. The apparatus of claim 18, wherein the compression layers comprise:
a first layer configured to process a specific type of the input battery data;
a second layer configured to perform primary compression by performing a first pooling operation on an output of the first layer;
a third layer configured to apply a batch normalization (BN) and a nonlinear function to an output of the second layer; and
a fourth layer configured to perform secondary compression by performing a second pooling operation on an output of the third layer.

20. The apparatus of claim 18, wherein the detection layer group comprises a fully connected (FC) layer configured to classify the feature data into one of different resistance levels of the non-short circuit state and the short circuit state and output indications of the classifications.
